(19) United States
(12) Patent Application Publication
(10) Pub. No.: US 2010/0090693 A1
(43) Pub. Date: Apr. 15, 2010

(54) METHOD AND APPARATUS FOR CONTROLLING T1 RECOVERY PROCESS IN MAGNETIC RESONANCE MEASUREMENTS

(76) Inventors: Lawrence L. Wald, Cambridge, MA (US); Susie Y. Huang, San Ramon, CA (US); Thomas Witzel, Cambridge, MA (US)

Correspondence Address: QUARLES & BRADY LLP, 411 E. WISCONSIN AVENUE, SUITE 2040, MILWAUKEE, WI, 53202-4497, US

(21) Appl. No.: 12/250,625

(22) Filed: Oct. 14, 2008

(51) Int. Cl. G01R 33/36; G01R 33/54

(52) U.S. Cl. 324/307; 324/322

(57) ABSTRACT

Radiation damping (RD) is employed to hasten the recovery of longitudinal magnetization after RF excitation and signal readout in a magnetic resonance measurement cycle. A switch driven by the pulse sequence that performs the measurement cycle energizes a feedback RF coil driven by an amplified and phase shifted portion of the received MR signal. The recovery of longitudinal magnetization is thus under direct control of the MR system and enables the reduction of the otherwise inefficient waiting times that are required for natural T1 recovery of the excited spin magnetization. This enables shortened acquisition times, improved sensitivity, better spatial and temporal resolution, and reduction of motion artifacts that result from long acquisition times.

### BACKGROUND OF THE INVENTION

The field of the invention is nuclear magnetic resonance imaging methods and systems. More particularly, the invention relates to the controlled recovery of longitudinal magnetization after the readout of MR signals from a pulse sequence.

When a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, or longitudinal magnetization, may be rotated, or “tipped”, into the x-y plane to produce a net transverse magnetic moment, or transverse magnetization. An MR signal is emitted by the excited spins after the excitation signal B₁ is terminated and this MR signal may be received and processed to form an image.

When utilizing these signals to produce images, magnetic field gradients (Gₓ, G_{y} and G_{z}) are employed. Typically, the region to be imaged is scanned by a sequence of measurement cycles in which these gradients vary according to the particular localization method being used. The resulting set of received MR signals are digitized and processed to reconstruct the image using one of many well known reconstruction techniques. There are numerous known measurement cycles that may be performed under the direction of prescribed pulse sequences.

An important objective in MR imaging and spectroscopy is to reduce the total scan time needed to perform the sequence of measurement cycles. It is possible to reduce the number of measurement cycles and their duration, but this generally results in the loss of image quality.

As shown in FIG. 3, a measurement cycle is comprised of a magnetization excitation and preparation portion 1, followed by an MR signal readout portion 2. If the pulse sequence can be ended at this point and immediately repeated, the measurement cycle can be very quickly performed and repeated to acquire all the needed data in a very short scan time. However, such a prompt repetition of the pulse sequence is not possible without a substantial loss of acquired MR signal strength and consequent loss of image signal to noise ratio (SNR). This is due to the fact that the longitudinal magnetization that is excited to produce the MR signal needs a substantial recovery time before the measurement cycle is repeated. This recovery time is known as the T₁ relaxation time and in biologic subjects it ranges from 500 to 2500 ms in duration. As a result, the repetition time (TR) between successive repeats of the measurement cycle must be extended well after the MR signal is acquired as shown in FIG. 3.

Methods are known for reducing this magnetization recovery time. One approach is referred to generally as driven equilibrium (DE) or fast recover (FR). It is implemented by applying a 180° RF refocusing pulse after the MR signal readout 2, followed by another 90° RF pulse precisely at the moment the resulting echo signal refocuses. This combination of RF pulses flips the transverse magnetization back to the longitudinal axis in preparation for the repeat of the pulse sequence. The most successful uses of this method are incorporated into a spin echo sequence, so that the flip-back pulse occurs when the echo is refocusing. This is key to the FR or DE method since any phase error accrued will cause the magnetization to miss the z axis, even possibly going to the −z axis. Therefore, successful implementation in a gradient echo sequence requires the addition of a 180° refocusing pulse after the readout and then the flip-back pulse. This negatively impacts SAR, minimum TE and introduces T2 weighting. SSFP sequences (True FISP) can be viewed as using a “flip-back” pulse to achieve high levels of steady state magnetization even with short TR and high flip angles. SSFP, however, leaves room for improvements since it does not achieve full equilibrium magnetization and suffers from phase accrual, causing the “flip-back” to miss the z axis. Thus only short TR are possible, and banding artifacts occur for off-resonance spins.

Radiation damping (RD) is a magnetic resonance phenomenon that has long been known in high field, high resolution liquid-state NMR where the RF coil sensitivity and quality factor is very high. Understood for decades, RD is an undesirable phenomenon whereby the nuclear magnetization acts back on itself via the induced currents in the radio-frequency (RF) coil used for detection. It is a manifestation of the detection process in that the induced currents in the coil (which is what the imager detects) themselves create a magnetic field known as the radiation damping field. The RD field rotates the spin magnetization back to its equilibrium direction at a characteristic rate that is distinct from longitudinal or T1 relaxation. Unlike T1 relaxation, which restores the length of the magnetization vector to its equilibrium value, the RD field does not alter the length of the magnetization vector. Rather, the RD field is an oscillating RF field that is on-resonance with the spins, since it was created by the precessing magnetization. It therefore has a resonant excitation effect on the spins, in a manner similar to an external RF excitation pulse. The RD effect is larger in high-resolution spectroscopy at high fields using small samples, and it is considered a nuisance in this regime (it shortens recovery and thus broadens spectral lines). Therefore, methods have been developed for reducing the RD effect through an external feedback device. The external device senses the current induced by the spins in the circuit and uses an external feedback device to cancel or reduce this current and thus its effect on the spinning magnetization. Such a solution is disclosed in U.S. Pat. No. 5,767,677.

### SUMMARY OF THE INVENTION

The present invention is a method and apparatus for controlling the duration of the magnetization recovery period in a magnetic resonance measurement cycle by employing the radiation damping (RD) phenomenon. More specifically, the received MR signal is coupled to a feedback circuit which imposes a phase shift and amplifies the resulting RD feedback signal. This RD feedback signal is applied to an RF coil disposed near the subject of the MR examination and its field quickly restores longitudinal magnetization in the subject. Referring particularly to FIG. 4, this radiation damping indicated by reference number 3 is applied after the MR signal readout 2 and it enables the next measurement cycle to be performed in a much shorter TR without loss of signal or image SNR.

This invention recognizes that the feedback circuit can be used to enhance the RD effect and that the increased RD effect can be employed to enable controlled and vastly accelerated recovery of the longitudinal magnetization. In preliminary experiments, we have found that we can achieve 100% of the recovery of the longitudinal magnetization by activating the feedback device for only 10 ms. On the other hand, natural T1 recovery in this sample (e.g., brain tissue) takes more than 3000 ms to achieve a 95% recovery by natural T1 relaxation. The feedback enhanced RD effect can thus be employed to substantially reduce the TR of existing pulse sequences.

An object of the present invention is to shorten total scan time by shortening the TR of pulse sequences used to acquire data. Using the feedback enhanced RD effect, a scan performed with the RARE imaging sequence (also known as Fast Spin Echo (FSE) or Turbo Spin Echo (TSE) may be shortened. In this scan a long TR is typically used to allow full recovery of the longitudinal magnetization by natural T1 processes. For sequences with a limited number of slices, this leads to excessive dead time. For example, the excitation and encoding period of a typical 12-echo sequence is about 150 ms. If a 256 image matrix is desired, this requires 256/12=22 excitations to acquire the imaging matrix. At a TR=3 s per excitation this requires over a minute of scan time. If the same longitudinal recovery is achieved in 10 ms of enhanced RD feedback, then the TR can be set to 160 ms, providing an imaging time of less than 2 s. Since the efficiency of the recovery is improved the image sensitivity would be identical, but with a vast saving in imaging time, and improved efficacy for movement in difficult patient populations.

Another object of the present invention is to increase the sensitivity of existing pulse sequences and thereby increase the SNR of the image reconstructed from the data they acquire. For example, in a typical spoiled gradient-recalled echo pulse sequence such as FLASH, a short TR is used to obtain acceptable imaging times, but the long (approximately 1 s) T1 recovery of tissue requires a low flip angle RF excitation pulse be used to ensure longitudinal magnetization is preserved for the duration of the scan. This greatly reduces the sensitivity of the image. For a proton density-weighted FLASH image, typically a TR of 50 ms and flip angle of 10° is used to preserve the high level of steady state magnetization needed to maintain proton density contrast. By providing full T1 recovery using the present invention within the 50 ms TR, a 90 degree RF excitation may be used, which improves the sensitivity and SNR by a factor of 7.

### BRIEF DESCRIPTION OF THE DRAWINGS

FIG. 1 is a block diagram of an MRI system which employs the present invention;

FIG. 2 is a block diagram of the transceiver used in the MR system of FIG. 1 which employs a preferred embodiment of an RD feedback circuit that employs the present invention;

FIG. 3 is a pictorial representation of a conventional pulse sequence used to perform an MR measurement cycle on the MR system of FIG. 1;

FIG. 4 is a pictorial representation of a pulse sequence that employs the present invention;

FIG. 5 is a graphic representation of a pulse sequence that employs the present invention;

FIG. 6 is a flowchart setting forth the steps of a radiation damping calibration technique in accordance with the present invention; and

FIG. 7 is a pictorial representation of a pulse sequence used perform a radiation damping technique of FIG. 6.

### DESCRIPTION OF THE PREFERRED EMBODIMENT

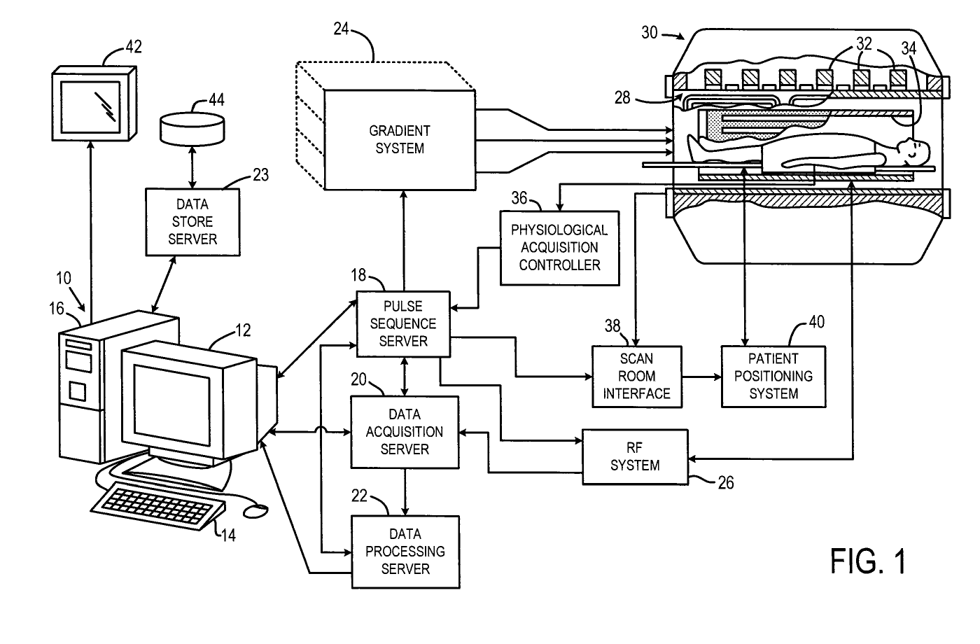

Referring particularly to FIG. 1, the preferred embodiment of the invention is employed in an MRI system. The MRI system includes a workstation 10 having a display 12 and a keyboard 14. The workstation 10 includes a processor 16 which is a commercially available programmable machine running a commercially available operating system. The workstation 10 provides the operator interface which enables scan prescriptions to be entered into the MRI system.

The workstation 10 is coupled to four servers: a pulse sequence server 18; a data acquisition server 20; a data processing server 22, and a data store server 23. In the preferred embodiment the data store server 23 is performed by the workstation processor 16 and associated disc drive interface circuitry. The server 18 is performed by a separate processor and the servers 20 and 22 are combined in a single processor. The workstation 10 and each processor for the servers 18, 20 and 22 are connected to an Ethernet communications network. This network conveys data that is downloaded to the servers 18, 20 and 22 from the workstation 10, and it conveys data that is communicated between the servers.

The pulse sequence server 18 functions in response to instructions downloaded from the workstation 10 to operate a gradient system 24 and an RF system 26. Gradient waveforms necessary to perform the prescribed scan are produced and applied to the gradient system 24 which excites gradient coils in an assembly 28 to produce the magnetic field gradients Gₓ, G_{y} and G_{z} used for position encoding NMR signals. The gradient coil assembly 28 forms part of a magnet assembly 30 which includes a polarizing magnet 32 and a whole-body RF coil 34.

RF excitation waveforms are applied to the RF coil 34 by the RF system 26 to perform the prescribed magnetic resonance pulse sequence. Responsive NMR signals detected by the RF coil 34 are received by the RF system 26, amplified, demodulated, filtered and digitized under direction of commands produced by the pulse sequence server 18. The RF system 26 includes an RF transmitter for producing a wide variety of RF pulses used in MR pulse sequences. The RF transmitter is responsive to the scan prescription and direction from the pulse sequence server 18 to produce RF pulses of the desired frequency, phase and pulse amplitude waveform. The generated RF pulses may be applied to the whole body RF coil 34 or to one or more local coils or coil arrays.

The RF system 26 also includes one or more RF receiver channels. Each RF receiver channel includes an RF amplifier that amplifies the NMR signal received by the coil to which it is connected and a quadrature detector which detects and digitizes the in-phase (I) and quadrature (Q) components of the received NMR signal. The magnitude of the received NMR signal may thus be determined at any sampled point by the square root of the sum of the squares of the I and Q components:

M=\sqrt{I²+Q²},

and the phase of the received NMR signal may also be determined:

φ=tan⁻¹Q/I.

The pulse sequence server 18 also optionally receives patient data from a physiological acquisition controller 36. The controller 36 receives signals from a number of different sensors connected to the patient, such as ECG signals from electrodes or respiratory signals from a bellows. Such signals are typically used by the pulse sequence server 18 to synchronize, or “gate”, the performance of the scan with the subject's respiration or heart beat.

The pulse sequence server 18 also connects to a scan room interface circuit 38 which receives signals from various sensors associated with the condition of the patient and the magnet system. It is also through the scan room interface circuit 38 that a patient positioning system 40 receives commands to move the patient to desired positions during the scan.

The digitized NMR signal samples produced by the RF system 26 are received by the data acquisition server 20. The data acquisition server 20 operates in response to instructions downloaded from the workstation 10 to receive the real-time NMR data and provide buffer storage such that no data is lost by data overrun. In some scans the data acquisition server 20 does little more than pass the acquired NMR data to the data processor server 22. However, in scans which require information derived from acquired NMR data to control the further performance of the scan, the data acquisition server 20 is programmed to produce such information and convey it to the pulse sequence server 18. For example, during prescans NMR data is acquired and used to calibrate the pulse sequence performed by the pulse sequence server 18. Also, navigator signals may be acquired during a scan and used to adjust RF or gradient system operating parameters or to control the view order in which k-space is sampled. And, the data acquisition server 20 may be employed to process NMR signals used to detect the arrival of contrast agent in an MRA scan. In all these examples the data acquisition server 20 acquires NMR data and processes it in real-time to produce information which is used to control the scan.

The data processing server 22 receives NMR data from the data acquisition server 20 and processes it in accordance with instructions downloaded from the workstation 10. Such processing may include, for example: Fourier transformation of raw k-space NMR data to produce two or three-dimensional images; the application of filters to a reconstructed image; the performance of a backprojection image reconstruction of acquired NMR data; the calculation of functional MR images; the calculation of motion or flow images, etc.

Images reconstructed by the data processing server 22 are conveyed back to the workstation 10 where they are stored. Real-time images are stored in a data base memory cache (not shown) from which they may be output to operator display 12 or a display 42 which is located near the magnet assembly 30 for use by attending physicians. Batch mode images or selected real time images are stored in a host database on disc storage 44. When such images have been reconstructed and transferred to storage, the data processing server 22 notifies the data store server 23 on the workstation 10. The workstation 10 may be used by an operator to archive the images, produce films, or send the images via a network to other facilities.

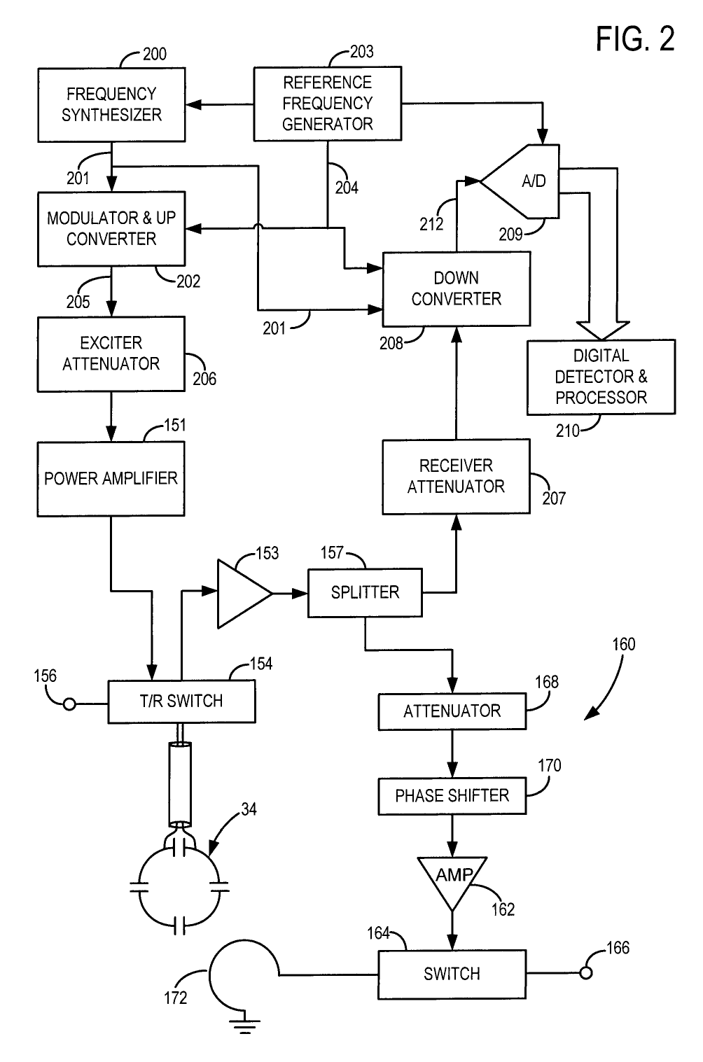

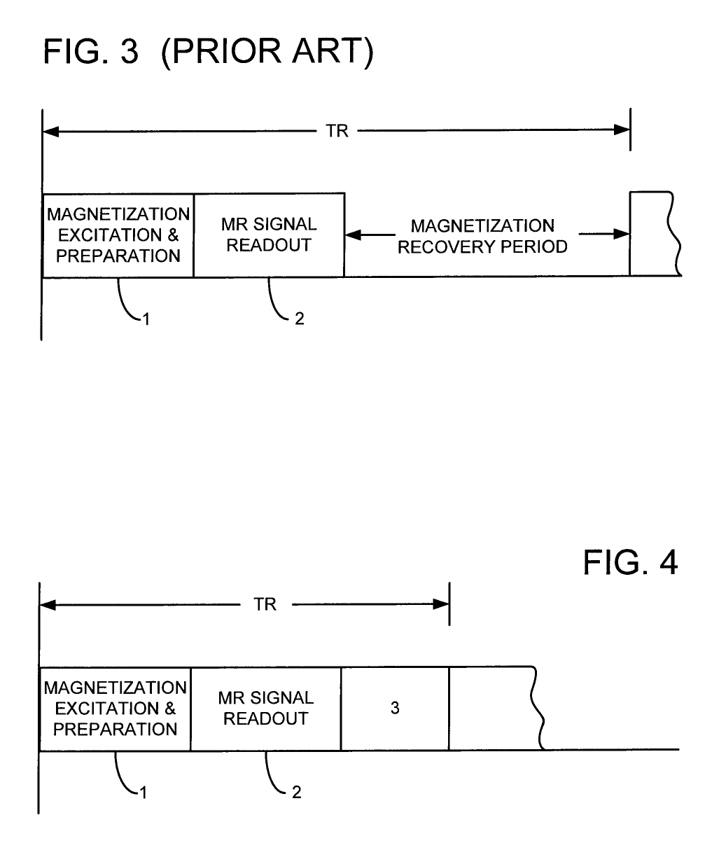

Referring particularly to FIG. 2, the RF system 26 includes a transmitter that produces a prescribed RF excitation field. The base, or carrier, frequency of this RF excitation field is produced under control of a frequency synthesizer 200 which receives a set of digital signals from the pulse sequence server 18. These digital signals indicate the frequency and phase of the RF carrier signal produced at an output 201. The RF carrier is applied to a modulator and up converter 202 where its amplitude is modulated in response to a signal R(t) also received from the pulse sequence server 18. The signal R(t) defines the envelope of the RF excitation pulse to be produced and is produced by sequentially reading out a series of stored digital values. These stored digital values may be changed to enable any desired RF pulse envelope to be produced.

The magnitude of the RF excitation pulse produced at output 205 is attenuated by an exciter attenuator circuit 206 which receives a digital command from the pulse sequence server 18. The attenuated RF excitation pulses are applied to the power amplifier 151 that drives the RF coil 34 through a transmit/receive (T/R) switch 154. The T/R switch 154 is operated by the pulse sequence server 18 through control line 156 to couple the power amplifier output to the coil 34 during the RF excitation phases of the pulse sequence and to connect the coil 34 to a receiver during other phases of the pulse sequence. As is well known in the art, separate transmit and receive coils can also be employed, in which case the T/R switch is not required.

Referring still to FIG. 2 the MR signal produced by the subject is picked up by the receive coil 34 and applied through a preamplifier 153 and splitter 157 to the input of a receiver attenuator 207. The receiver attenuator 207 further amplifies the signal by an amount determined by a digital attenuation signal received from the pulse sequence server 18. The received MR signal is at or around the Larmor frequency, and this high frequency signal is down converted in a two step process by a down converter 208 which first mixes the MR signal with the carrier signal on line 201 and then mixes the resulting difference signal with a reference signal on line 204. The down converted MR signal is applied to the input of an analog-to-digital (A/D) converter 209 which samples and digitizes the analog signal and applies it to a digital detector and signal processor 210 which produces 16-bit in-phase (I) values and 16-bit quadrature (Q) values corresponding to samples of the received signal. The resulting stream of digitized I and Q values of the received signal are output to the data acquisition server 20. The reference signal as well as the sampling signal applied to the A/D converter 209 are produced by a reference frequency generator 203.

Referring still to FIG. 2, the present invention is implemented by adding a controlled feedback loop indicated generally at 160. The splitter 157 conveys the acquired MR signal to the receiver as described above and it also conveys that signal to the feedback loop 160. The feedback MR signal is attenuated to a prescribed level by an attenuator 168 and fed to the input of a phase shifter 170. The MR feedback signal is then amplified in a low noise amplifier 162 and applied to the input of a switch 164. Like the T/R switch 154, the feedback switch 164 is controlled by the pulse sequence server 18 through a control line 166. The switch 164 is a pin diode driven by an operational amplifier that is turned on by the trigger signal on line 166. The feedback MR signal is turned on during a prescribed period during the pulse sequence as will be described below. The attenuation and phase shift is set for each prescribed pulse sequence that employs the MR feedback such that the recovery of the longitudinal magnetization is driven to a desired level in a desired time period. The attenuated and phase shifted feedback MR signal is applied to a separate RF feedback coil 172 that is positioned near the subject being examined.

The RF feedback coil 172 is a conventional MR coil that is designed to operate at the Larmor frequency of the MR system. It produces a uniform magnetic field through the region of interest in the subject being examined. The mutual inductance between the feedback coil 172 and the other active RF coil 34 is minimized. The size of the feedback coil 172 is selected to optimize the strength of the RF field that is fed back to the subject of the examination.

As indicated generally above, the feedback switch 166 is operated during a pulse sequence after the MR signal is read out to produce a phase shifted and amplified MR feedback signal that exploits the radiation damping (RD) effect. The timing of the radiation damping and the magnitude thereof is under control of the MR system. As a result, the recovery of the longitudinal magnetization is also under the control of the MR system.

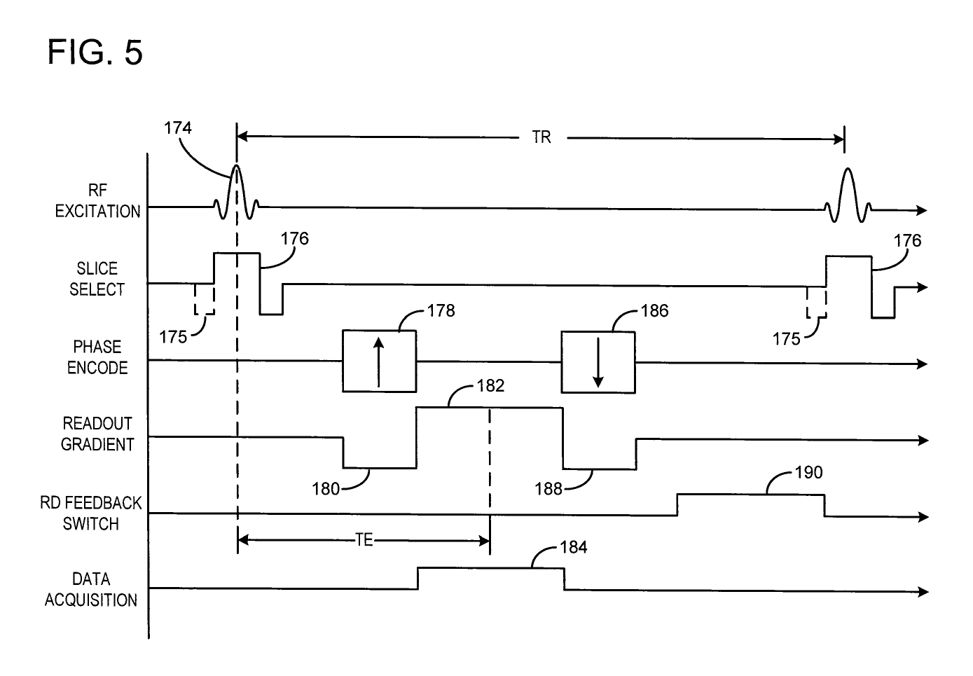

While the present invention may be used in many different pulse sequences, its use in a FLASH pulse sequence is particularly advantageous. Referring to FIG. 5, a FLASH pulse sequence that employs the present invention includes a selective RF excitation pulse 174 that is produced in the presence of a slice select gradient 176. Phase encoding is applied next by a gradient lobe 178 and a dephasing lobe 180 that forms part of a readout gradient waveform is also applied. An MR signal is then acquired during the application of a readout gradient 182 and this is coupled as described above to the system receiver where it is digitized. Following the data acquisition period indicated at 184, the phase encoding is rewound by gradient lobe 186 and a rephasing lobe 188 on the readout gradient waveform produces a gradient-recalled MR echo signal immediately thereafter.

Referring still to FIG. 5, the RD feedback switch described above is operated to produce the RD feedback signal as indicated at 190. In this preferred embodiment the duration of the RD feedback 190 is 10 ms and then the next repetition of the FLASH pulse sequence begins. The longitudinal magnetization is driven to full recovery during this 10 ms RF feedback signal application. Shorter RD feedback signal periods can also be used when it is not necessary to achieve full restoration of the magnetization. For example, the magnetization can be 95% fully restored with a period of only 5 ms.

The present invention can be used with many different pulse sequences. In some cases it is desirable to destroy any transverse magnetization that remains after the driven magnetization recovery and before the pulse sequence is repeated. Crusher gradients may be applied to accomplish this and the sequence becomes a spoiled FLASH sequence. Or, the gradient waveforms can be altered to fully refocus the spin magnetization prior to its next repetition and the pulse sequence is an SSFP sequence. This can be done, for example, by adding a negative lobe to the slice select gradient waveform as indicated by dotted line 175.

The amplitude and phase of the RD feedback is calibrated in a procedure that is performed periodically by maintenance personnel for each receive coil to be used. This calibration procedure provides estimates of the values to be used with the particular receive coil. The same calibration procedure is also performed in a prescan after the receive coil and subject of the examination are in place in the bore of the magnet. This prescan optimizes the RD feedback amplitude and phase shift settings.

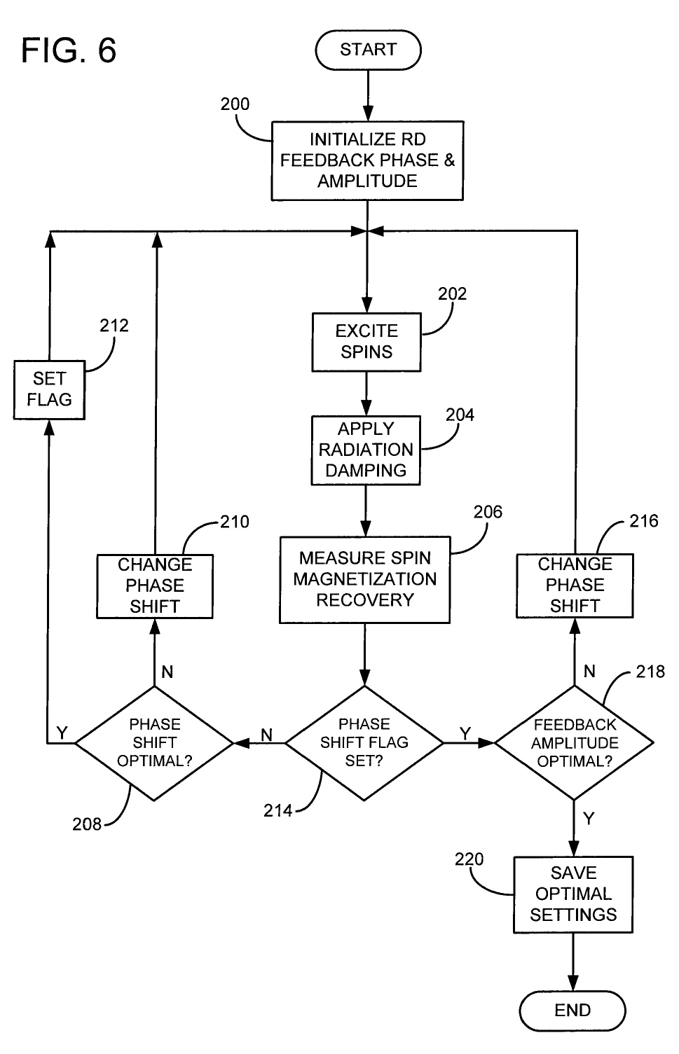

Referring particularly to FIG. 6, the calibration process begins by initializing the values of the RD feedback amplitude and phase shift as indicated at process block 200. When performed during a patient prescan, these initial settings are those determined during the previous service calibration. A loop is then entered in which the phase shift and amplitude of the RD feedback are adjusted until optimal settings are obtained.

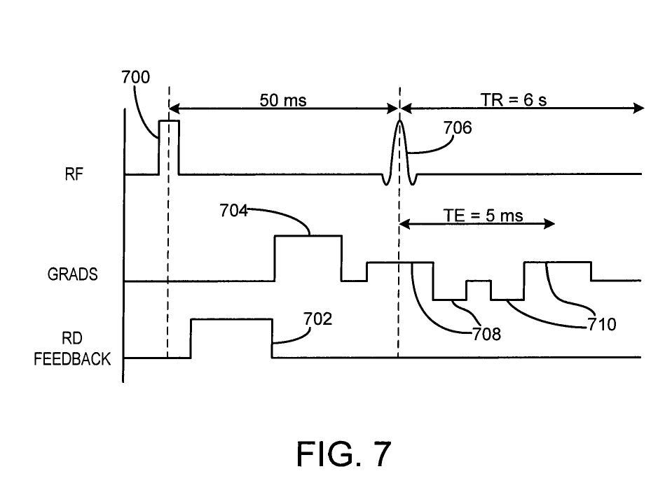

More specifically, a pulse sequence shown in FIG. 7 is performed in which spins in the region of interest in the subject are excited with a 90° RF excitation pulse 700 as indicated at process block 202. The saturated spins are then subjected to a period of radiation damping as indicated at process block 204 using the current phase shift and amplitude settings for the RD feedback signal 702. The radiation damping period is preferably set in the 10 ms to 15 ms range and immediately thereafter the magnetization recovery is measured as indicated at process block 206. This is a pulse sequence that includes the application of crusher gradients 704 to dephase any remaining transverse magnetization, followed by the application of another 90° RF excitation pulse 706 during a slice selection gradient 708 to excite the region of interest in the patient. 5 ms later, a readout gradient waveform 710 is applied and the magnitude of the FID signal is obtained and stored as a measurement of the effectiveness of the current RD feedback signal settings.

Referring still to FIG. 6, the first part of the calibration process uses the above measurement sequence to determine the optimal phase shift setting. As indicated at decision block 208, the FID signal magnitude is tested. If the peak signal has not been reached, the phase shift setting is changed as indicated at process block 210 and the measurement sequence is repeated. It has been discovered that RD feedback effectiveness is very sensitive to the phase shift setting and that the proper setting is detected when the FID amplitude reaches a peak and then starts to decline as the phase settings are stepped through a series of values. When the peak phase shift setting is determined, a flag is set as indicated at process block 212 and the second stage of the calibration process is begun as detected at decision block 214.

Referring still to FIG. 6, the feedback amplitude setting is optimized by repeating the measurement sequence and changing the RD feedback signal amplitude as indicated at process block 216. Unlike the phase shift, there is no detectable peak setting. Instead, as the RF feedback signal amplitude is increased the measured magnetization recovery improves asymptotically. The amplitude setting is optimized when a continued increase in RD feedback signal amplitude produces less than a preset minimum increase in detected FID signal amplitude as determined at decision block 218. When this occurs the calibration process is completed by storing the optimal settings for subsequent use during patient scanning as indicated at process block 220.

The present invention has been described in terms of one or more preferred embodiments, and it should be appreciated that many equivalents, alternatives, variations, and modifications, aside from those expressly stated, are possible and within the scope of the invention.

1. A method for controlling the elements of a magnetic resonance system to perform a measurement cycle, the method comprising:
a) performing an RF excitation sequence for producing transverse magnetization in a subject;
b) performing a signal readout sequence for acquiring a magnetic resonance (MR) signal produced by the transverse magnetization; and
c) performing a radiation damping sequence that includes applying a radiation damping field to the subject which is derived from the MR acquired signal and which accelerates recovery of longitudinal magnetization in the subject.

2. The method as recited in claim 1 in which step c) includes phase shifting a portion of the acquired MR signal; and
producing an RF field in the subject using the phase shifted MR signal to accelerate longitudinal magnetization recovery in the subject.

3. A feedback circuit for use in a magnetic resonance system to control the magnetization recovery of spin magnetization during an MR measurement cycle which comprises:
a splitter for receiving an MR signal during the measurement cycle;
a switch connected to receive the MR signal from the splitter and being operable under the control of the MR system to produce the MR signal at its output;
a phase shifter connected to the output of the switch and being operable to apply a phase shift to the MR signal; and
an RF feedback coil connected to receive the phase shifted MR signal from the phase shifter and produce a magnetic field in a subject being examined by the measurement cycle.

4. The feedback circuit as recited in claim 3 which includes an amplifier that amplifies the MR signal applied to the RF feedback coil.

5. The feedback circuit as recited in claim 3 which includes an attenuator that attenuates the MR signal applied to the phase shifter.

6. The feedback circuit as recited in claim 3 wherein the size of the RF feedback coil is selected to optimize the strength of the RF field that is fed back to the subject of the examination.

7. A method for acquiring magnetic resonance (MR) signals from a subject placed in a magnetic resonance imaging (MRI) system, the steps comprising:
a) performing a prescan in which an optimal setting for a radiation damping feedback circuit is determined;
b) performing a series of pulse sequences with the MRI system to acquire a corresponding series of MR signals; and
c) performing a radiation damping sequence after each pulse sequence is performed to cause the radiation damping circuit to produce a radiation damping feedback signal at the optimal setting to accelerate recovery of longitudinal magnetization in the subject.

8. The method as recited in claim 7 wherein the optimal setting for a radiation damping feedback circuit includes at least one of an optimal phase shift setting and an optimal magnitude setting.

9. The method as recited in claim 8 wherein an optimal phase shift setting for the radiation damping circuit is determined by performing a pulse sequence that includes:
a ) i) applying an RF excitation pulse to excite spins in a region of interest;
a) ii) subjecting the excited spins to a period of radiation damping at an initial phase shift setting for the radiation damping feedback circuit;
a) iii) measuring the spin magnetization recovery;
a) iv) repeating steps a) i) through a) iii) with different phase shift settings until optimum spin magnetization recovery is obtained; and
a) v) storing the optimal phase shift settings.

10. The method as recited in claim 9 wherein step a) further includes:
a) vi) applying crusher gradients to dephase any transverse magnetization that remains after the period of radiation damping;
